(19) United States
(12) Patent Application Publication
(10) Pub. No.: US 2026/0101574 A1
(43) Pub. Date: Apr. 9, 2026

(54) SEMICONDUCTOR DEVICE STRUCTURE AND METHODS OF FORMING THE SAME

(71) Applicant: TAIWAN SEMICONDUCTOR MANUFACTURING COMPANY, LTD., Hsinchu (TW)

(72) Inventors: Jung-Hung CHANG, Changhua (TW); Tsung-Han CHUANG, Tainan (TW); Shih-Cheng CHEN, New Taipei (TW); Fu-Cheng CHANG, Hsinchu (TW); Kuo-Cheng CHIANG, Hsinchu (TW); Chih-Hao WANG, Hsinchu (TW)

(21) Appl. No.: 19/037,816

(22) Filed: Jan. 27, 2025

Related U.S. Application Data
(60) Provisional application No. 63/703,969, filed on Oct. 6, 2024.

(51) Int. Cl. H10D 84/83; H10D 62/10; H10D 64/01; H10D 84/01; H10D 84/85

(52) U.S. Cl. CPC H10D 84/8312; H10D 62/116; H10D 84/013; H10D 84/0151; H10D 84/8311; H10D 84/832; H10D 64/017; H10D 84/851; H10D 84/856

(57) ABSTRACT

Embodiments of the present disclosure provide a semiconductor device structure and methods for forming the same. The structure includes a first semiconductor layer disposed in a first region, a second semiconductor layer disposed over the first semiconductor layer in the first region, a first gate electrode layer disposed between the first and second semiconductor layers in the first region, a first dielectric spacer disposed adjacent the first gate electrode layer in the first region, a third semiconductor layer disposed in a second region, a fourth semiconductor layer disposed over the third semiconductor layer in the second region, a second gate electrode layer disposed between the third and fourth semiconductor layers in the second region, and a second dielectric spacer disposed adjacent the second gate electrode layer in the second region. The second dielectric spacer has a thickness smaller than a first thickness of the first dielectric spacer.

### CROSS-REFERENCE TO RELATED APPLICATIONS

This application claims priority to U.S. Provisional Application Ser. No. 63/703,969 filed Oct. 6, 2024, which is incorporated by reference in its entirety.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs.

Therefore, there is a need to improve processing and manufacturing ICs.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1, 2, 3, 4, and 5 are perspective views of various stages of manufacturing a semiconductor device structure, in accordance with some embodiments.

FIGS. 6, 7, 8, 9, 10, 11, 12, 13, 14, 15, 16, 17, 18, 19, 20, and 21 are cross-sectional side views of various stages of manufacturing the semiconductor device structure taken along line A-A of FIG. 5, in accordance with some embodiments.

FIG. 19-1 is a cross-sectional side view of one of various stages of manufacturing the semiconductor device structure taken along line B-B of FIG. 5, in accordance with some embodiments.

FIGS. 22A, 22B, and 22C are cross-sectional side views of one of various stages of manufacturing the semiconductor device structure taken along line A-A of FIG. 5, in accordance with alternative embodiments.

FIG. 22D is a cross-sectional side view of one of various stages of manufacturing the semiconductor device structure taken along line B-B of FIG. 5, in accordance with some embodiments.

FIGS. 23, 24, and 25 are cross-sectional side views of various stages of manufacturing the semiconductor device structure taken along line A-A of FIG. 5, in accordance with alternative embodiments.

FIGS. 26, 27, 28, 29, and 30 are cross-sectional side views of various stages of manufacturing the semiconductor device structure taken along line A-A of FIG. 5, in accordance with alternative embodiments.

FIG. 31A is a cross-sectional side view of one of various stages of manufacturing the semiconductor device structure taken along line A-A of FIG. 5, in accordance with alternative embodiments.

FIG. 31B is a cross-sectional side view of one of various stages of manufacturing the semiconductor device structure taken along line B-B of FIG. 5, in accordance with alternative embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “over,” “on,” “top,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

While the embodiments of this disclosure are discussed with respect to nanostructure channel FETs, such as Horizontal Gate All Around (HGAA) FETs, Vertical Gate All Around (VGAA) FETs, Forksheet FETs, implementations of some aspects of the present disclosure may be used in other processes and/or in other devices, such as FinFETs, planar FETs, and other suitable devices. A person having ordinary skill in the art will readily understand other modifications that may be made are contemplated within the scope of this disclosure. In cases where gate all around (GAA) transistor structures are adapted, the GAA transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

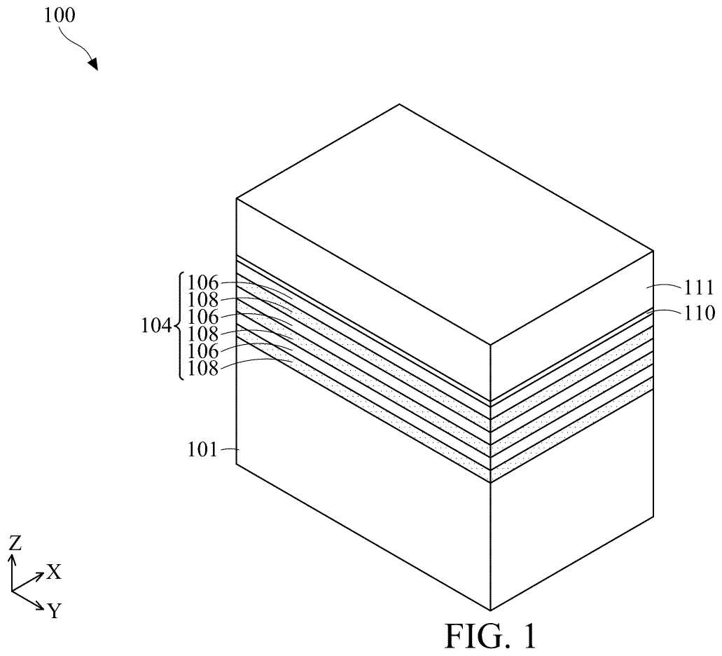

FIG. 1-21 show exemplary processes for manufacturing a semiconductor device structure 100 according to embodiments of the present disclosure. It is understood that additional operations can be provided before, during, and after processes shown by FIG. 1-21, and some of the operations described below can be replaced or eliminated, for additional embodiments of the method. The order of the operations/processes is not limiting and may be interchangeable.

FIGS. 1, 2, 3, 4, and 5 are perspective views of various stages of manufacturing a semiconductor device structure 100, in accordance with some embodiments. As shown in FIG. 1, a semiconductor device structure 100 includes a stack of semiconductor layers 104 formed over a front side of a substrate 101. The substrate 101 may be a semiconductor substrate. The substrate 101 may include a crystalline semiconductor material such as, but not limited to silicon (Si), germanium (Ge), silicon germanium (SiGe), gallium arsenide (GaAs), indium antimonide (InSb), gallium phosphide (GaP), gallium antimonide (GaSb), indium aluminum arsenide (InAlAs), indium gallium arsenide (InGaAs), gallium antimony phosphide (GaSbP), gallium arsenic antimonide (GaAsSb) and indium phosphide (InP).

The substrate 101 may include various regions that have been doped with impurities (e.g., dopants having p-type or n-type conductivity). Depending on circuit design, the dopants may be, for example phosphorus for an n-type field effect transistors (NFET) and boron for a p-type field effect transistors (PFET).

The stack of semiconductor layers 104 includes alternating semiconductor layers made of different materials to facilitate formation of nanostructure channels in a multi-gate device, such as nanostructure channel FETs. In some embodiments, the stack of semiconductor layers 104 includes first semiconductor layers 106 and second semiconductor layers 108. In some embodiments, the stack of semiconductor layers 104 includes alternating first and second semiconductor layers 106, 108. The first semiconductor layers 106 and the second semiconductor layers 108 are made of semiconductor materials having different etch selectivity and/or oxidation rates. For example, the first semiconductor layers 106 may be made of Si and the second semiconductor layers 108 may be made of SiGe. In some examples, the first semiconductor layers 106 may be made of SiGe and the second semiconductor layers 108 may be made of Si. Alternatively, in some embodiments, either of the semiconductor layers 106, 108 may be or include other materials such as Ge, SiC, GeAs, GaP, InP, InAs, InSb, GaAsP, AlInAs, AlGaAs, InGaAs, GaInP, GaInAsP, or any combinations thereof.

The first and second semiconductor layers 106, 108 are formed by any suitable deposition process, such as epitaxy. By way of example, epitaxial growth of the layers of the stack of semiconductor layers 104 may be performed by a molecular beam epitaxy (MBE) process, a metalorganic chemical vapor deposition (MOCVD) process, and/or other suitable epitaxial growth processes.

The first semiconductor layers 106 or portions thereof may form nanostructure channel(s) of the semiconductor device structure 100 in later fabrication stages. The term nanostructure is used herein to designate any material portion with nanoscale, or even microscale dimensions, and having an elongate shape, regardless of the cross-sectional shape of this portion. Thus, this term designates both circular and substantially circular cross-section elongate material portions, and beam or bar-shaped material portions including, for example, a cylindrical in shape or substantially rectangular cross-section. The nanostructure channel(s) of the semiconductor device structure 100 may be surrounded by a gate electrode. The semiconductor device structure 100 may include a nanostructure transistor. The nanostructure transistors may be referred to as nanosheet transistors, nanowire transistors, gate-all-around (GAA) transistors, multi-bridge channel (MBC) transistors, or any transistors having the gate electrode surrounding the channels. The use of the first semiconductor layers 106 to define a channel or channels of the semiconductor device structure 100 is further discussed below.

Each first semiconductor layer 106 may have a thickness in a range between about 4 nm and about 30 nm. Each second semiconductor layer 108 may have a thickness that is equal, less, or greater than the thickness of the first semiconductor layer 106. In some embodiments, each second semiconductor layer 108 has a thickness in a range between about 2 nm and about 50 nm. Three first semiconductor layers 106 and three second semiconductor layers 108 are alternately arranged as illustrated in FIG. 1, which is for illustrative purposes and not intended to be limiting beyond what is specifically recited in the claims. It can be appreciated that any number of first and second semiconductor layers 106, 108 can be formed in the stack of semiconductor layers 104, and the number of layers depending on the predetermined number of channels for the semiconductor device structure 100. As shown in FIG. 1, an oxide layer 110 is formed on the topmost first semiconductor layer 106, and a nitride layer 111 is formed on the oxide layer 110. The oxide layer 110 may be silicon oxide and may have different etch selectivity compared to the nitride layer 111. The nitride layer 111 may include any suitable nitride material, such as silicon nitride. In some embodiments, the oxide layer 110 and the nitride layer 111 may be a mask structure.

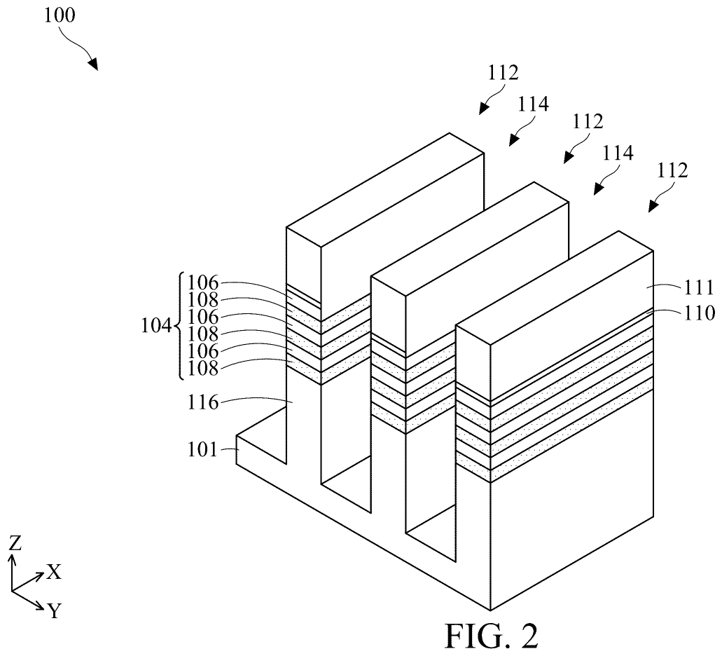

In FIG. 2, fin structures 112 are formed from the stack of semiconductor layers 104. Each fin structure 112 has an upper portion including the semiconductor layers 106, 108 and a substrate portion 116 formed from the substrate 101. The fin structures 112 may be formed by patterning a hard mask layer, such as the oxide layer 110 and the nitride layer 111, using multi-patterning operations including photo-lithography and etching processes. The etching process can include dry etching, wet etching, reactive ion etching (RIE), and/or other suitable processes. The photo-lithography process may include forming a photoresist layer (not shown) over the hard mask layer, exposing the photoresist layer to a pattern, performing post-exposure bake processes, and developing the photoresist layer to form a masking element including the photoresist layer. In some embodiments, patterning the photoresist layer to form the masking element may be performed using an electron beam (e-beam) lithography process. The etching process forms trenches 114 in unprotected regions through the hard mask layer, through the stack of semiconductor layers 104, and into the substrate 101, thereby leaving the plurality of extending fin structures 112. The trenches 114 extend along the X direction. The trenches 114 may be etched using a dry etch (e.g., RIE), a wet etch, and/or combination thereof.

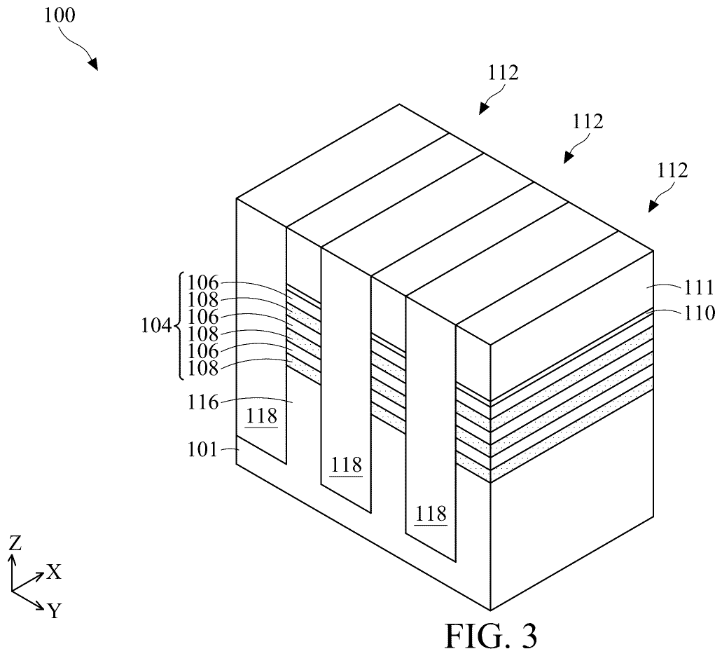

As shown in FIG. 3, after the fin structures 112 are formed, an insulating material 118 is formed on the substrate 101. The insulating material 118 fills the trenches 114 between neighboring fin structures 112 until the fin structures 112 are embedded in the insulating material 118. Then, a planarization operation, such as a chemical mechanical polishing (CMP) method and/or an etch-back method, is performed such that the top of the fin structures 112 is exposed. The insulating material 118 may be made of silicon oxide, silicon nitride, silicon oxynitride (SiON), SiOCN, SiCN, fluorine-doped silicate glass (FSG), a low-K dielectric material, or any suitable dielectric material. The insulating material 118 may be formed by any suitable method, such as low-pressure chemical vapor deposition (LPCVD), plasma enhanced CVD (PECVD) or flowable CVD (FCVD).

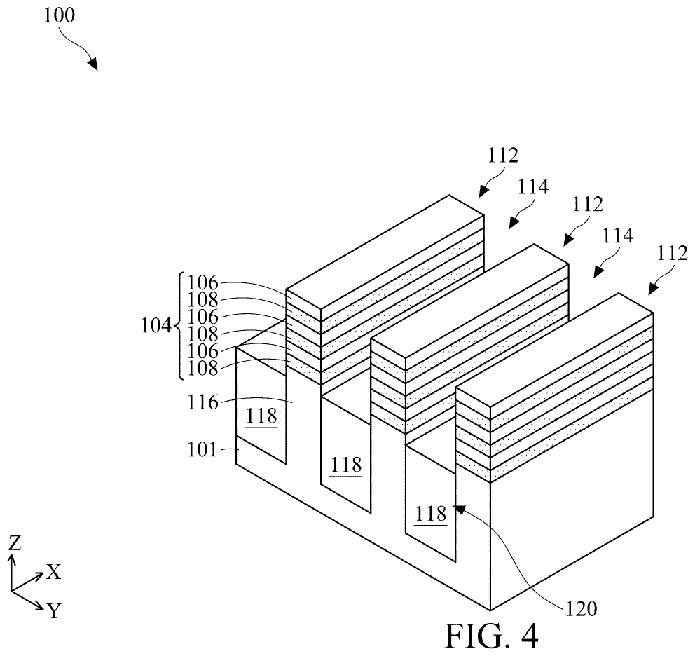

As shown in FIG. 4, the insulating material 118 is recessed to form isolation regions 120. The recess of the insulating material 118 exposes portions of the fin structures 112, such as the stack of semiconductor layers 104. The recess of the insulating material 118 reveals the trenches 114 between the neighboring fin structures 112. The isolation regions 120 may be formed using a suitable process, such as a dry etching process, a wet etching process, or a combination thereof. A top surface of the insulating material 118 may be level with or below a surface of the second semiconductor layers 108 in contact with the substrate portion 116 formed from the substrate 101. In some embodiments, the isolation regions 120 are the shallow trench isolation (STI) regions.

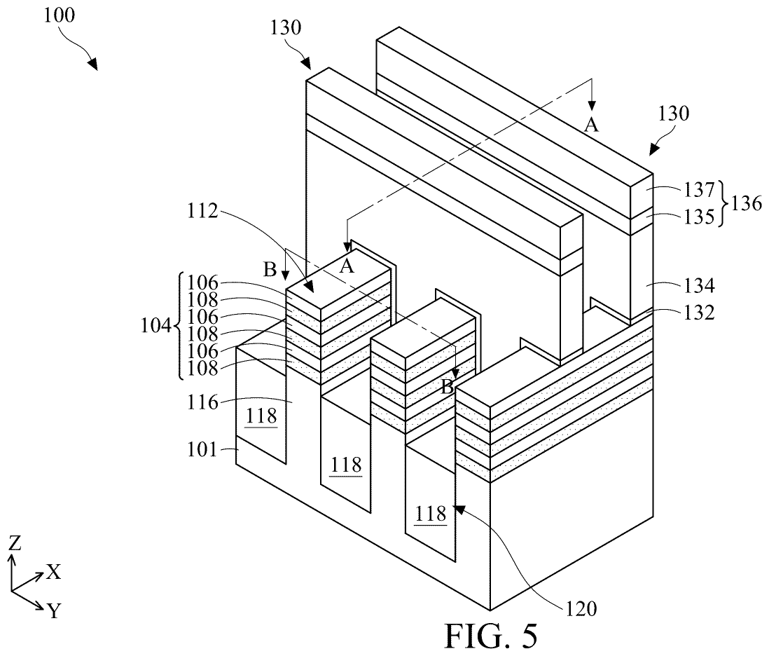

In FIG. 5, one or more sacrificial gate structures 130 are formed over the semiconductor device structure 100. The sacrificial gate structures 130 are formed over first portions of the fin structures 112 and first portions of the isolation regions 120, while second portions of the fin structures 112 and second portions of the isolation regions 120 are exposed. Each sacrificial gate structure 130 may include a sacrificial gate dielectric layer 132, a sacrificial gate electrode layer 134, and a mask layer 136. In some embodiments, the mask layer 136 is a multi-layer structure. For example, the mask layer 136 includes an oxide layer 135 and a nitride layer 137 formed on the oxide layer 135. The sacrificial gate dielectric layer 132, the sacrificial gate electrode layer 134, and the mask layer 136 may be formed by sequentially depositing blanket layers of the sacrificial gate dielectric layer 132, the sacrificial gate electrode layer 134, and the mask layer 136, and then patterning those layers into the sacrificial gate structures 130. The sacrificial gate dielectric layer 132 may include one or more layers of dielectric material, such as a silicon oxide-based material. The sacrificial gate electrode layer 134 may include silicon, such as polycrystalline silicon or amorphous silicon. The first portions of the fin structures 112 that are covered by the sacrificial gate electrode layer 134 of the sacrificial gate structure 130 serve as channel regions for the semiconductor device structure 100.

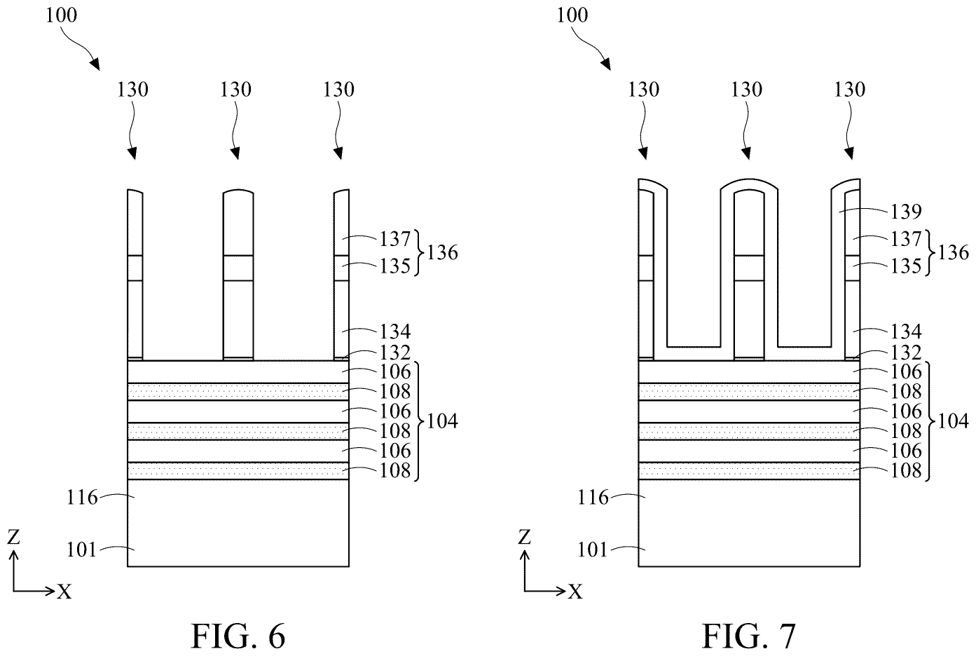

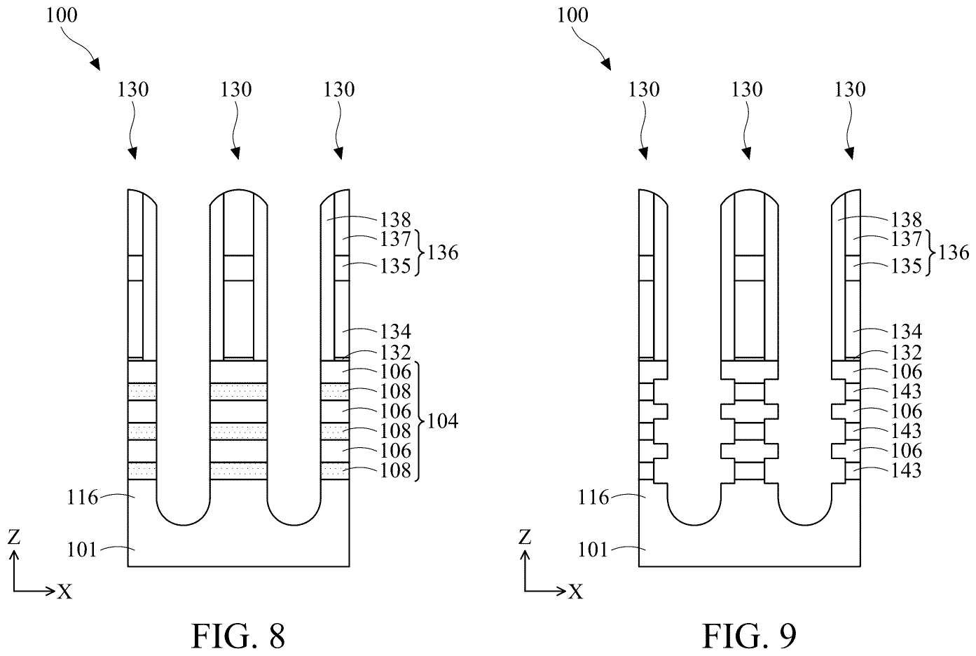

FIGS. 6, 7, 8, 9, 10, 11, 12, 13, 14, 15, 16, 17, 18, 19, 20, and 21 are cross-sectional side views of various stages of manufacturing the semiconductor device structure 100 taken along line A-A of FIG. 5, in accordance with some embodiments. FIG. 6 is a cross-sectional view of the semiconductor device structure 100 shown in FIG. 5. Next, as shown in FIG. 7, a dielectric layer 139 is formed on the semiconductor device structure 100. In some embodiments, the dielectric layer 139 is deposited around the sacrificial gate structures 130. The dielectric layer 139 may include a single layer or multiple layers. The dielectric layer 139 may be made of a dielectric material such as silicon oxide, silicon nitride, silicon carbide, silicon oxynitride, SiCN, silicon oxycarbide, SiOCN, and/or combinations thereof. Next, as shown in FIG. 8, an anisotropic etch process is performed to remove portions of the dielectric layer 139 to form spacers 138 on sidewalls of the sacrificial gate structures 130.

As shown in FIG. 8, after forming the spacers 138, the second portions of the fin structures 112 not covered by the sacrificial gate structure 130 and the spacers 138 are recessed to a level above, at, or below the top surfaces of the isolation regions 120 (FIG. 5). The recessing of the second portions of the fin structures 112 can be done by an etch process, either isotropic or anisotropic etch process, and the etch process may be selective with respect to the semiconductor materials of the first and second semiconductor layers 106, 108. The etch process may be a dry etch, such as a RIE, NBE, or the like, or a wet etch, such as using tetramethyalammonium hydroxide (TMAH), ammonium hydroxide (NH₄OH), or any suitable etchant.

Next, as shown in FIG. 9, the second semiconductor layers 108 are removed and replaced with a dielectric material 143. The second semiconductor layers 108 may be removed by a selective etch process, such as a selective dry etch process, a selective wet etch process, or a combination thereof. In some embodiments, the selective etch process does not substantially affect the first semiconductor layers 106. The removal of the second semiconductor layers 108 form openings between vertically adjacent first semiconductor layers 106, and the dielectric material 143 is formed in the openings and on the exposed surfaces of the semiconductor device structure 100. In some embodiments, the dielectric material 143 is an oxide formed by any suitable process, such as ALD, CVD, PECVD, or FCVD. In some embodiments, the oxide is silicon oxide. Next, as shown in FIG. 9, an etch back process is performed to remove portions of the dielectric material 143 other than the portions of the dielectric material 143 formed between vertically adjacent first semiconductor layers 106. In some embodiments, the etch back process is an anisotropic etching process. At this stage, edge portions of the dielectric material 143 and edge portions of the first semiconductor layers 106 have substantially flat surfaces which may be flush with side surfaces of the spacers 138. Next, as shown in FIG. 9, edge portions of the dielectric material 143 are removed horizontally along the X direction. In other words, the dielectric material 143 is recessed along the X direction. The removal of the edge portions of the dielectric material 143 forms cavities. In some embodiments, the edge portions of the dielectric material 143 are removed by a selective wet etch process.

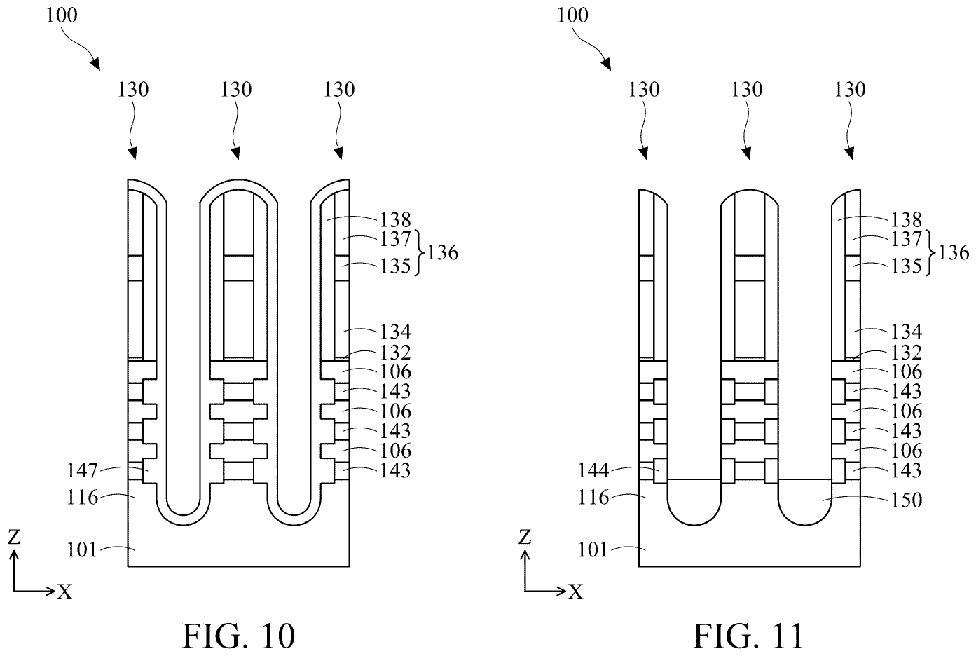

In FIG. 10, a dielectric layer 147 is deposited on the semiconductor device structure 100 and in the cavities. The dielectric layer 147 may be made of a dielectric material, such as SiO, SiON, SiCN, SiOC, SiOCN, or SiN. The dielectric layer 147 may be formed by a conformal deposition process, such as ALD.

In FIG. 11, dielectric spacers 144 are formed by removing portions of the dielectric layer 147. In some embodiments, the portions of the dielectric layer 147 are removed by an anisotropic etching process. The dielectric spacers 144 are protected by the first semiconductor layers 106 during the anisotropic etching process. The dielectric material 143 is capped between the dielectric spacers 144 along the X direction, as shown in FIG. 11.

After the formation of the dielectric spacers 144, a semiconductor layer 150 is formed on the exposed substrate portions 116, as shown in FIG. 11. The semiconductor layer 150 may be formed adjacent the substrate portion 116 located under the bottommost second semiconductor layer 108, as shown in FIG. 11. In some embodiments, the semiconductor layer 150 includes undoped silicon or undoped SiGe. The semiconductor layer 150 may be first formed on semiconductor surfaces, such as on the exposed substrate portions 116 and on the semiconductor layers 106, by epitaxy. In some embodiments, the semiconductor layer 150 is crystalline silicon or crystalline SiGe. A subsequent etch process is performed to remove the portions of the semiconductor layer 150 formed on the first semiconductor layers 106. In some embodiments, the semiconductor layer 150 has a thickness ranging from about 5 nm to about 50 nm along the Z direction.

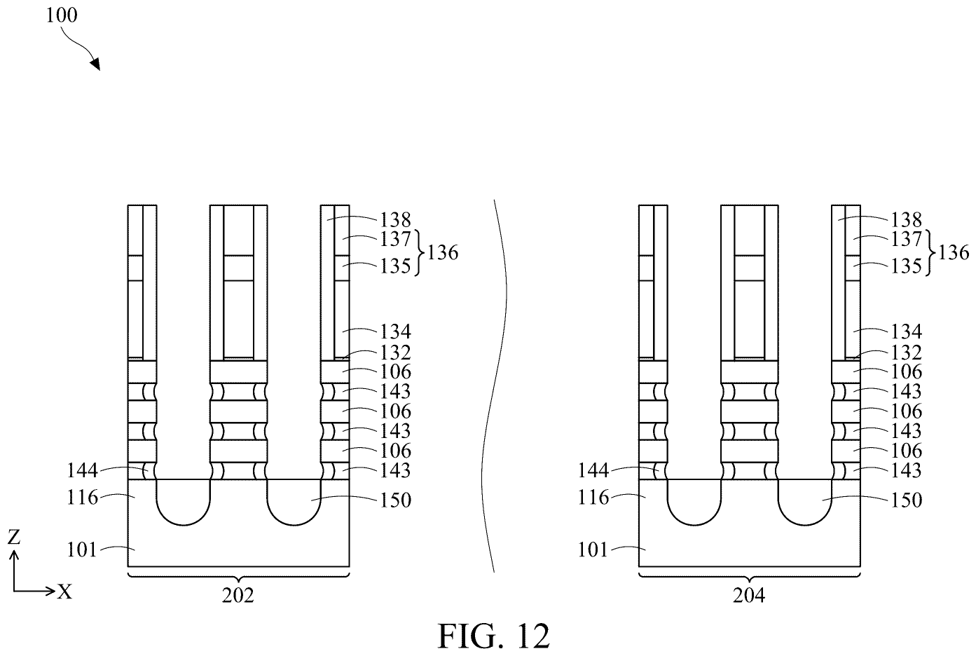

In some embodiments, regions of the semiconductor device structure 100 in which n-type devices or p-type devices are formed are respectively referred to herein as “NMOS regions” or “PMOS regions.” As shown in FIG. 12, the semiconductor device structure 100 includes a PMOS region 202 and an NMOS region 204, which is at the manufacturing stage shown in FIG. 11.

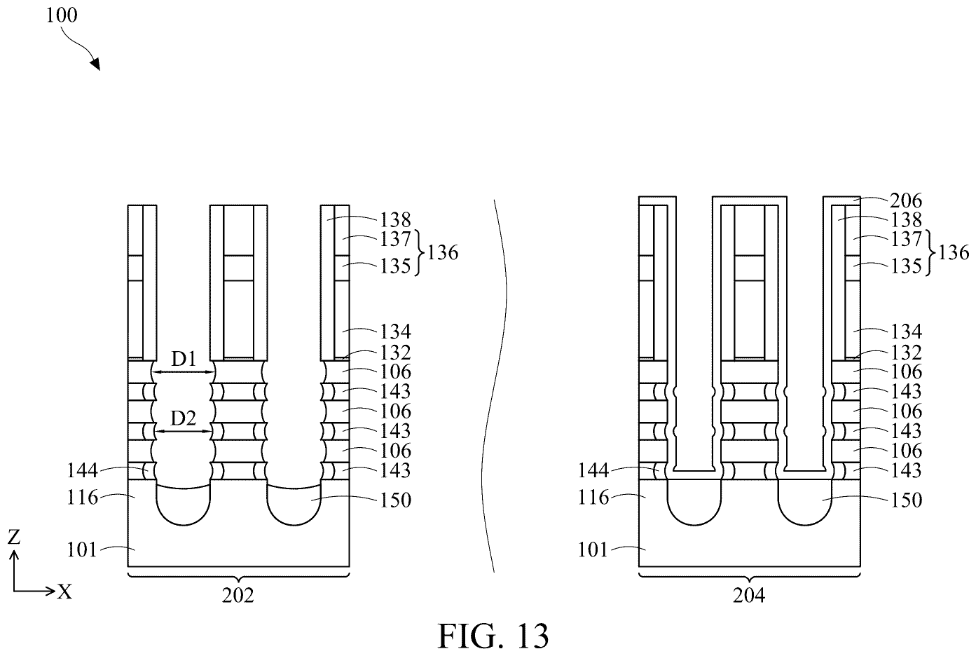

Next, as shown in FIG. 13, a mask layer 206 is deposited in the NMOS region 204, and the opening between adjacent stacks of first semiconductor layers 106 and dielectric material 143 along the X direction in the PMOS region 202 is enlarged. The mask layer 206 may include any suitable material. In some embodiments, the mask layer 206 is a metal oxide layer and is formed by an ALD process. The mask layer 206 may be initially formed in the PMOS region 202 and the NMOS region 204, and the portion of the mask layer 206 formed in the PMOS region 202 is removed. The portion of the mask layer 206 formed in the NMOS region 204 may be protected by a patterned mask. Next, an etch process is performed to enlarge the opening between adjacent stacks of first semiconductor layers 106 and dielectric material 143 along the X direction in the PMOS region 202. The etch process may be an isotropic etch process. In some embodiments, the etch process is a wet etch process. In some embodiments, the etch process utilizes an etchant that etches semiconductor materials at a faster rate than dielectric materials. For example, the etchant may remove portions of the first semiconductor layers 106 and the semiconductor layer 150, while the dielectric spacers 144 and the spacers 138 are substantially unaffected by the etchant. The etch process does not substantially affect the mask layer 206 formed in the NMOS region 204. In some embodiments, as a result of the etch process, the side surfaces of the first semiconductor layers 106 in the PMOS region 202 have concave profiles, and the top surface of the semiconductor layer 150 in the PMOS region 202 has a concave profile, as shown in FIG. 13. In some embodiments, as shown in FIG. 13, a distance D1 between adjacent first semiconductor layers 106 along the X direction is greater than a distance D2 between adjacent dielectric spacers 144 along the X direction in the PMOS region 202 as a result of the etch process. After enlarging the openings in the PMOS region 202, the mask layer 206 in the NMOS region 204 is removed. The mask layer 206 may be removed by any suitable process, such as a dry etch process, a wet etch process, or a combination thereof.

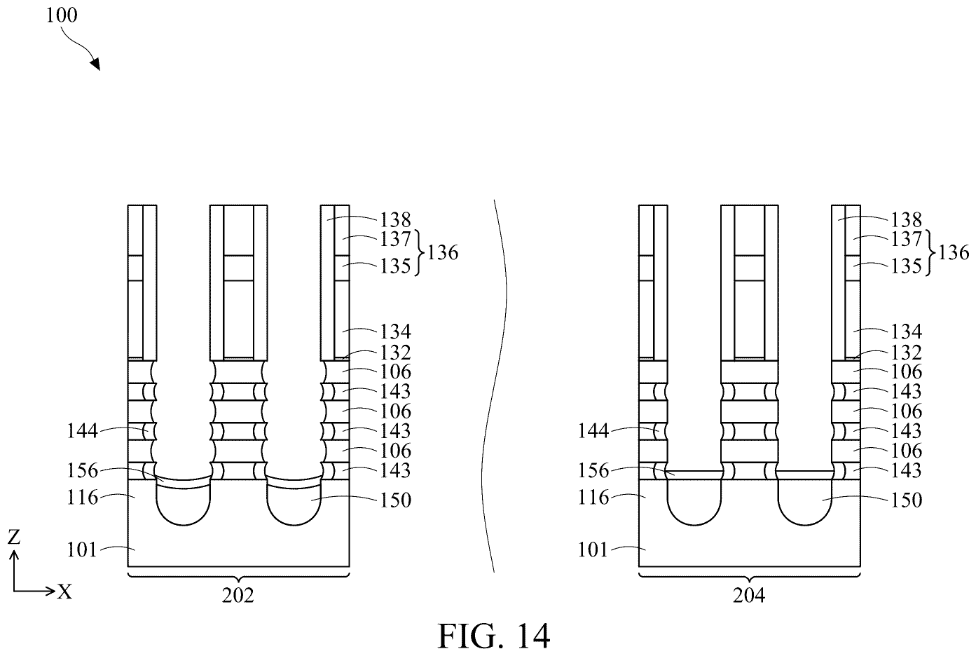

In FIG. 14, a dielectric layer 156 is formed on the semiconductor layer 150 in the PMOS region 202 and the NMOS region 204. The dielectric layer 156 may be formed by first forming a dielectric layer on the exposed surfaces of the semiconductor device structure 100, followed by one or more etch processes to remove portions of the dielectric layer other than the dielectric layer 156. A sacrificial layer (not shown), such as a bottom anti-reflective coating (BARC) layer, may be used to assist with the removal of the portions of the dielectric layer formed on the sidewalls of the spacers 138, the first semiconductor layers 106, and the dielectric spacers 144. The dielectric layer 156 may include any suitable dielectric material. In some embodiments, the dielectric layer 156 includes SiN. The dielectric layer 156 may be formed by any suitable process. In some embodiments, the dielectric layer 156 is formed by CVD or PECVD.

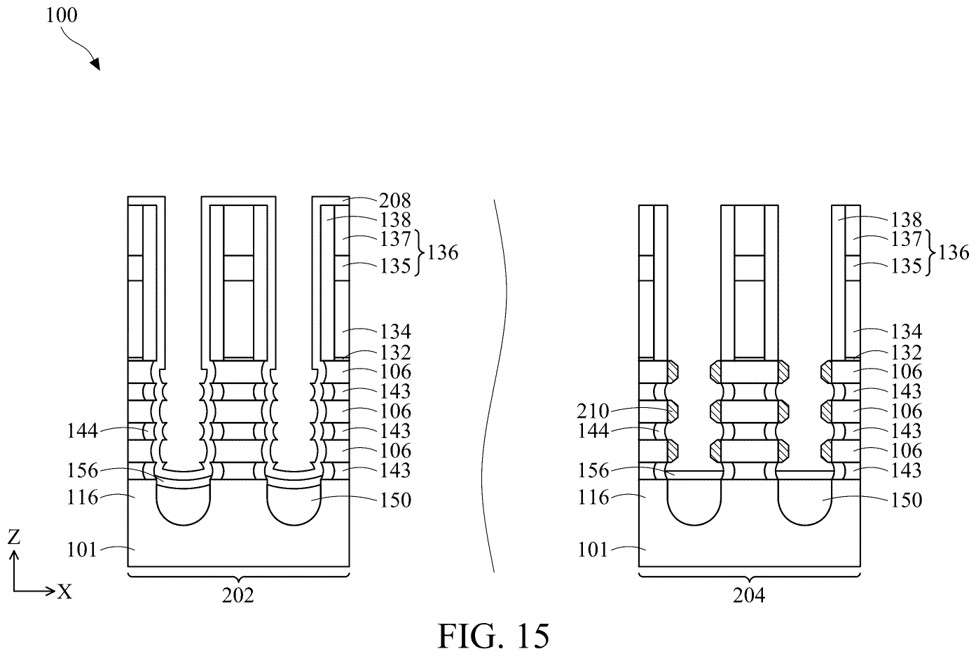

In FIG. 15, a mask layer 208 is formed in the PMOS region 202, and a semiconductor material 210 is formed on the first semiconductor layers 106 in the NMOS region 204. The mask layer 208 may include the same material as the mask layer 206 and may be formed by the same process as the mask layer 206. The semiconductor material 210 may include Si, SiP, SiC, SiCP, or other suitable semiconductor material. In some embodiments, the semiconductor material 210 may include an n-type dopant, such as Ar or P, and the semiconductor material 210 has a first dopant concentration. The semiconductor material 210 may be formed by an epitaxial growth method using CVD, ALD or MBE, and the semiconductor material 210 is not grown from the dielectric materials of the spacers 138, the dielectric spacers 144, the dielectric layer 156, and the mask layer 208. After the formation of the semiconductor material 210, the mask layer 208 is removed. The mask layer 208 may be removed by a selective etch process that does not substantially affect the spacers 138, the semiconductor material 210, the first semiconductor layers 106, and the dielectric spacers 144.

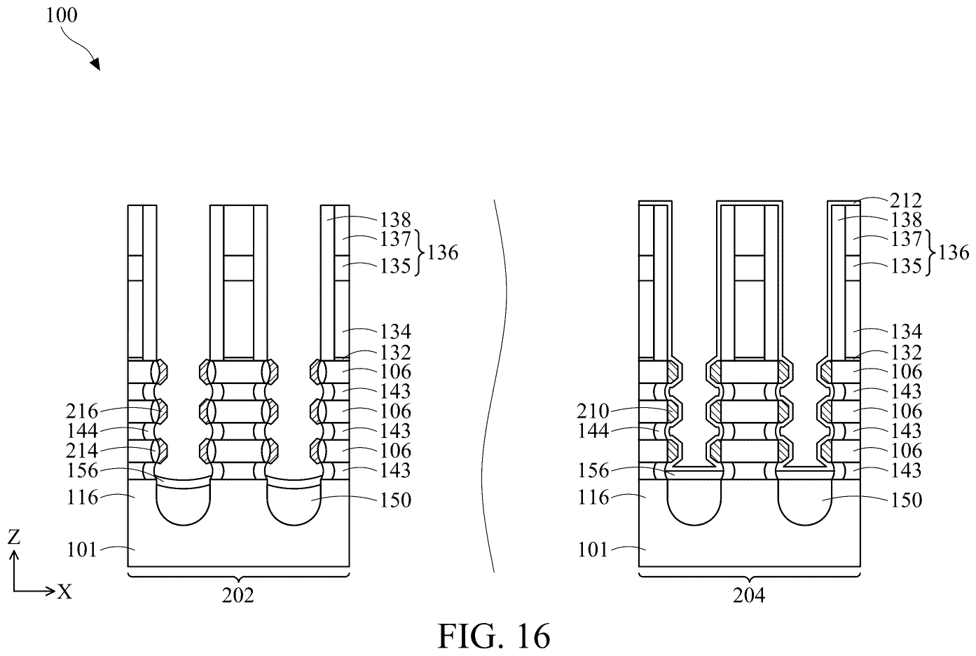

In FIG. 16, a mask layer 212 is formed in the NMOS region 204, and semiconductor materials 214, 216 are formed on the first semiconductor layers 106 in the PMOS region 202. The mask layer 212 may include the same material as the mask layer 206 and may be formed by the same process as the mask layer 206. The semiconductor material 214 may include Si, SiGe, Ge, or other suitable semiconductor material. In some embodiments, the semiconductor material 214 may include a p-type dopant, such as B, and the semiconductor material 214 has a second dopant concentration. The semiconductor material 214 may be formed by an epitaxial growth method using CVD, ALD or MBE, and the semiconductor material 214 is not grown from the dielectric materials of the spacers 138, the dielectric spacers 144, the dielectric layer 156, and the mask layer 212. Next, the semiconductor material 216 is formed on the semiconductor material 214. The semiconductor material 216 may include Si, SiGe, Ge, or other suitable semiconductor material. In some embodiments, the semiconductor material 216 may include a p-type dopant, such as B, and the semiconductor material 216 has a third dopant concentration. In some embodiments, the semiconductor materials 214, 216 include different materials, different compositions, or different dopant concentrations. In some embodiments, the third dopant concentration of the semiconductor material 216 is greater than the second dopant concentration of the semiconductor material 214. After the formation of the semiconductor material 216, the mask layer 212 is removed. The mask layer 208 may be removed by a selective etch process that does not substantially affect the spacers 138, the semiconductor material 210, the semiconductor material 216, and the dielectric spacers 144.

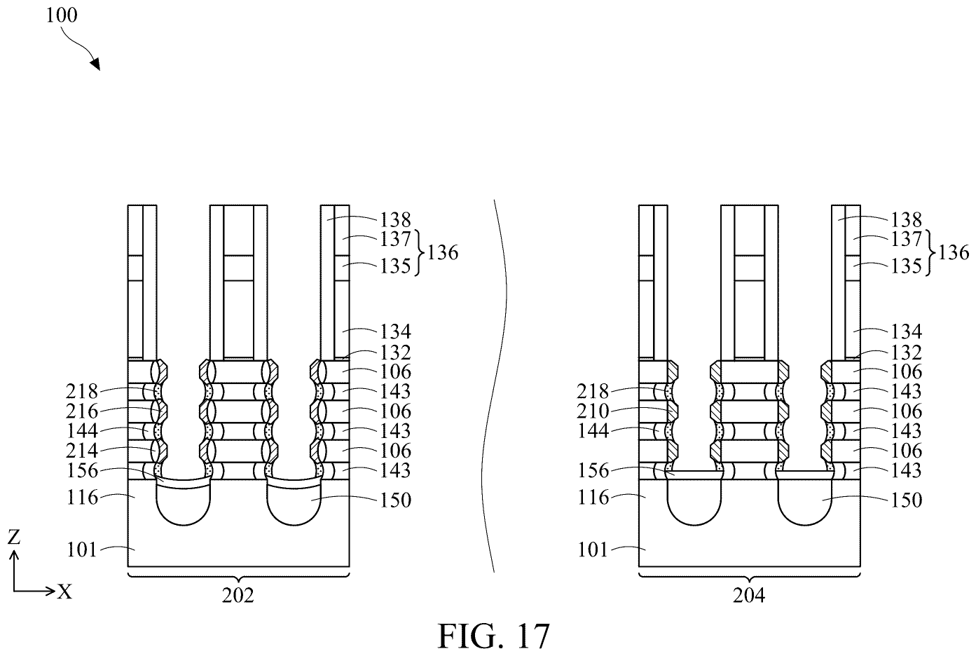

In FIG. 17, dielectric spacers 218 are formed on the dielectric spacers 144 in the PMOS region 202 and the NMOS region 204. The dielectric spacers 218 may include any suitable dielectric material. In some embodiments, the dielectric spacers 218 include the same material as the dielectric spacers 144. In some embodiments, the dielectric spacers 218 and the dielectric spacers 144 include different materials. The dielectric spacers 218 may be formed by first forming a conformal dielectric layer in the PMOS region 202 and the NMOS region 204, and an etch process is performed to remove portions of the conformal dielectric layer other than the dielectric spacers 218. In some embodiments, the etch process is an isotropic etch process, and the dielectric spacers 218 are protected by the semiconductor material 216 in the PMOS region 202 and by the semiconductor material 210 in the NMOS region 204. In some embodiments, as a result of the extra semiconductor material 216 in the PMOS region 202, the thickness of the dielectric spacer 218 along the X direction in the PMOS region 202 is greater than the thickness of the dielectric spacer 218 along the X direction in the NMOS region 204, as shown in FIG. 17. In some embodiments, the thickness of the dielectric spacer 144 along the X direction in the PMOS region 202 is the same as the thickness of the dielectric spacer 144 along the X direction in the NMOS region 204.

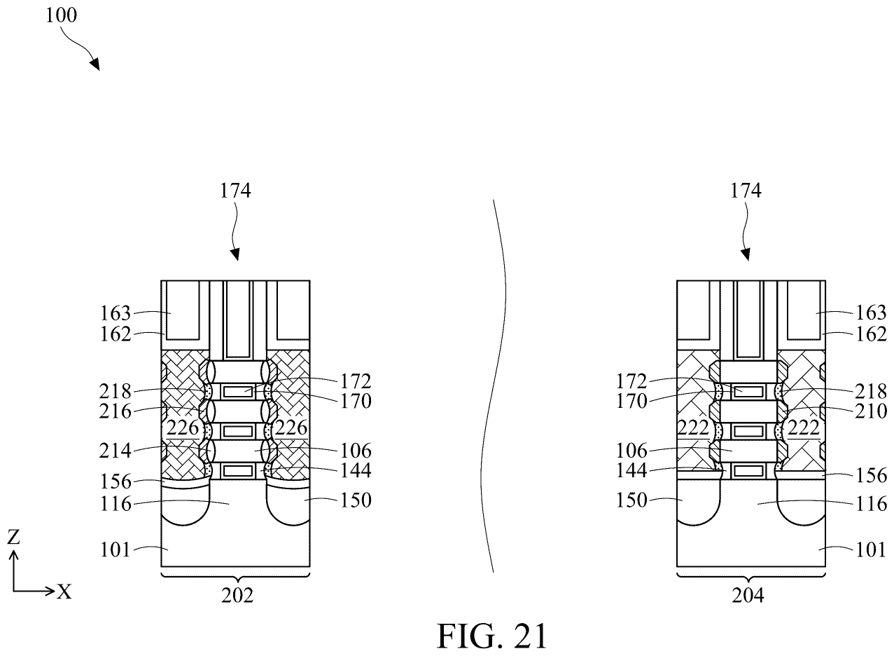

The dielectric spacers 144 are formed to electrically isolate the subsequently formed gate structures and the subsequently formed source/drain regions. If the thickness of the dielectric spacer 144 along the X direction is too thin, such as less than about 4 nm, the device effective capacitance (Ceff) may be increased. In order to form thick dielectric spacers 144, a thick dielectric layer 147 (FIG. 10) may be formed. However, as the distance between adjacent sacrificial gate structures 130 (FIG. 10) (or the gate structures 174 shown in FIG. 21) gets smaller, the dielectric layer 147 may fill the opening between adjacent first semiconductor layers 106 along the X direction. As a result, it would be more difficult to remove portions of the dielectric layer 147 to form the dielectric spacers 144. By forming the dielectric spacers 218 on the dielectric spacers 144, the combined thickness of the dielectric spacers 144, 218 is increased compared to the thickness of the single dielectric spacer 144. As a result, Ceff is reduced. In some embodiments, the dielectric spacer 144 has a thickness ranging from about 4 nm to about 8 nm, the dielectric spacer 218 has a thickness ranging from about 2 nm to about 3 nm, and the combined thickness ranges from about 6 nm to about 11 nm. In some embodiments, as described above, the combined thickness of the dielectric spacers 144, 218 in the PMOS region 202 is greater than the combined thickness of the dielectric spacers 144, 218 in the NMOS region 204.

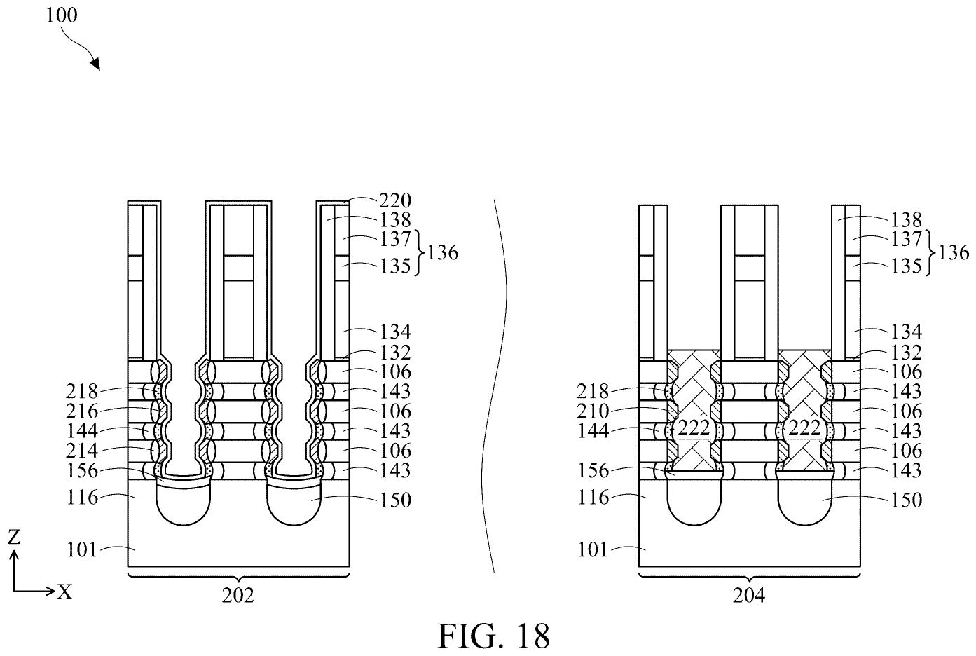

As shown in FIG. 18, a mask layer 220 is formed in the PMOS region 202, and a semiconductor material 222 is formed from the semiconductor material 210 in the NMOS region 204. The mask layer 220 may include the same material as the mask layer 206 and may be formed by the same process as the mask layer 206. The semiconductor material 222 may include Si, SiP, SiC, SiCP, or other suitable semiconductor material. In some embodiments, the semiconductor material 222 may include an n-type dopant, such as Ar or P, and the semiconductor material 222 has a fourth dopant concentration greater than the first dopant concentration of the semiconductor material 210. The semiconductor material 222 may be formed by an epitaxial growth method using CVD, ALD or MBE, and the semiconductor material 222 is not grown from the dielectric materials of the spacers 138, the dielectric spacers 218, the dielectric layer 156, and the mask layer 220. After the formation of the semiconductor material 222, the mask layer 220 is removed. The mask layer 220 may be removed by a selective etch process that does not substantially affect the spacers 138, the semiconductor material 222, the semiconductor material 216, and the dielectric spacers 218.

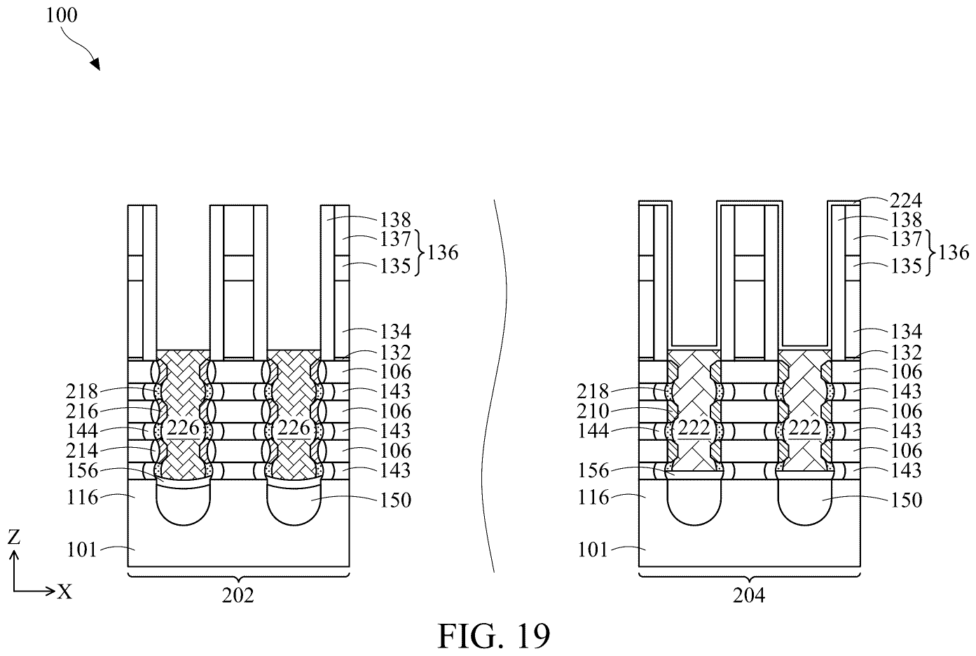

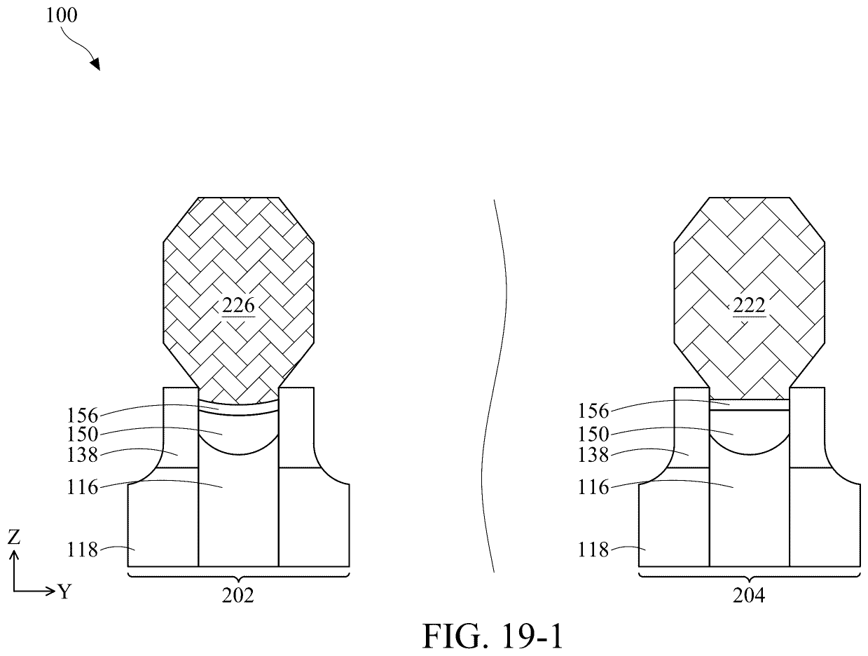

As shown in FIG. 19, a mask layer 224 is formed in the NMOS region 204, and a semiconductor material 226 is formed from the semiconductor material 216 in the PMOS region 202. The mask layer 224 may include the same material as the mask layer 206 and may be formed by the same process as the mask layer 206. The semiconductor material 226 may include Si, SiGe, Ge, or other suitable semiconductor material. In some embodiments, the semiconductor material 226 may include a p-type dopant, such as B, and the semiconductor material 226 has a fifth dopant concentration. In some embodiments, the semiconductor materials 216, 226 include different materials, different compositions, or different dopant concentrations. In some embodiments, the third dopant concentration of the semiconductor material 216 is less than the fifth dopant concentration of the semiconductor material 226. The semiconductor material 226 may be formed by an epitaxial growth method using CVD, ALD or MBE, and the semiconductor material 226 is not grown from the dielectric materials of the spacers 138, the dielectric spacers 218, the dielectric layer 156, and the mask layer 224. After the formation of the semiconductor material 226, the mask layer 224 is removed. The mask layer 224 may be removed by a selective etch process that does not substantially affect the spacers 138, the semiconductor material 222, and the semiconductor material 226.

The semiconductor materials 214, 216, 226 together may form a source/drain (S/D) region in the PMOS region 202, and the semiconductor materials 210, 222 together may form an S/D region in the NMOS region 204. In this disclosure, a source region and a drain region are interchangeably used, and the structures thereof are substantially the same. Furthermore, source/drain region(s) may refer to a source or a drain, individually or collectively dependent upon the context.

FIG. 19-1 is a cross-sectional side view of one of various stages of manufacturing the semiconductor device structure 100 taken along line B-B of FIG. 5, in accordance with some embodiments. As shown in FIG. 19-1, the semiconductor layer 150 is disposed on the substrate portion 116 in the PMOS region 202 and the NMOS region 204, the dielectric layer 156 is disposed on the semiconductor layer 150 in the PMOS region 202 and the NMOS region 204, the semiconductor material 226 is disposed on the dielectric layer 156 in the PMOS region 202, and the semiconductor material 222 is disposed on the dielectric layer 156 in the NMOS region 204.

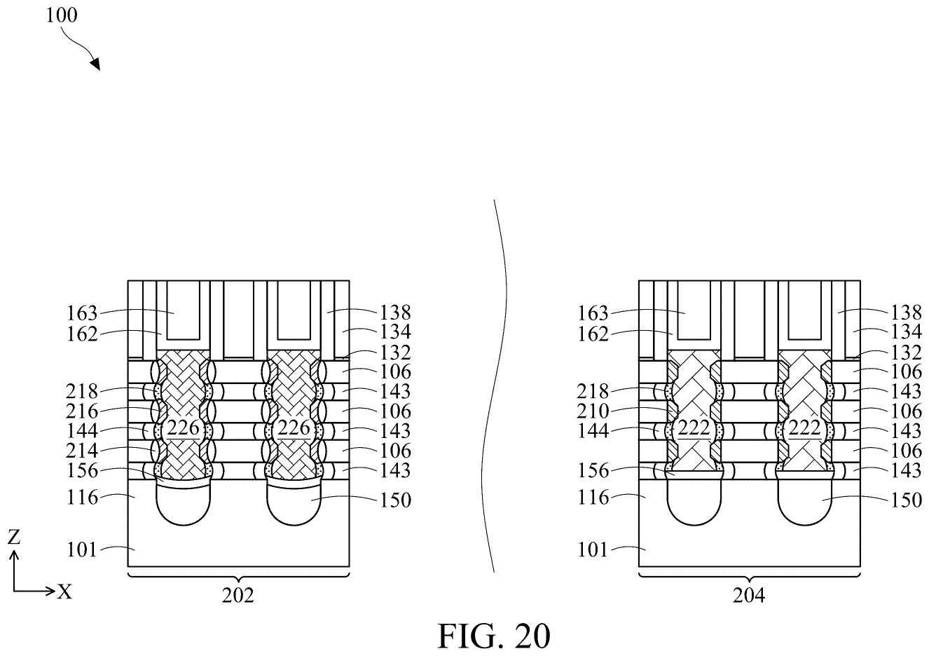

As shown in FIG. 20, a contact etch stop layer (CESL) 162 is conformally formed on the exposed surfaces of the semiconductor device structure 100, and a interlayer dielectric (ILD) layer 164 is formed on the CESL 162. The CESL 162 may include an oxygen-containing material or a nitrogen-containing material, such as silicon nitride, silicon carbon nitride, silicon oxynitride, carbon nitride, silicon oxide, silicon carbon oxide, or the like, or a combination thereof, and may be formed by CVD, PECVD, ALD, or any suitable deposition technique. The materials for the ILD layer 163 may include compounds including Si, O, C, and/or H, such as silicon oxide, SiCOH, or SiOC. Organic materials, such as polymers, may also be used for the ILD layer 163. The ILD layer 163 may be deposited by a PECVD process or other suitable deposition technique. In some embodiments, after formation of the ILD layer 163, the semiconductor device structure 100 may be subject to a thermal process to anneal the ILD layer 163.

A planarization process is performed to expose the sacrificial gate electrode layer 134, as shown in FIG. 20. The planarization process may be any suitable process, such as a CMP process. The planarization process removes portions of the ILD layer 163 and the CESL 162 disposed on the sacrificial gate structures 130. The planarization process may also remove the mask layer 136 (FIG. 19).

In FIG. 21, the sacrificial gate electrode layer 134, the sacrificial gate dielectric layer 132, and the dielectric material 143 are removed, exposing portions of the first semiconductor layer 106. The sacrificial gate electrode layer 134 may be first removed by any suitable process, such as dry etch, wet etch, or a combination thereof, followed by the removal of the sacrificial gate dielectric layer 132, which may be performed by any suitable process, such as dry etch, wet etch, or a combination thereof. In some embodiments, a wet etchant such as a tetramethylammonium hydroxide (TMAH) solution can be used to selectively remove the sacrificial gate electrode layer 134 but not the spacers 138, the ILD layer 163, and the CESL 162. In some embodiments, the dielectric material 143 is removed by a selective etch process. The selective etch process removes the dielectric material 143 between the first semiconductor layers 106 but does not remove the first semiconductor layers 106, the ILD layer 163, the CESL 162, and the spacers 138. In some embodiments, the sacrificial gate dielectric layer 132 and the dielectric material 143 are removed by the same selective etch process.

Next, after the formation of the nanostructure channels (i.e., the exposed portions of the first semiconductor layers 106), a gate dielectric layer 170 is formed to surround the exposed portions of the first semiconductor layers 106, and a gate electrode layer 172 is formed on the gate dielectric layer 170, as shown in FIG. 21. The gate dielectric layer 170 and the gate electrode layer 172 may be collectively referred to as a gate structure 174. In some embodiments, an interfacial layer (IL) (not shown) is formed between the gate dielectric layer 170 and the exposed surfaces of the first semiconductor layers 106. In some embodiments, the gate dielectric layer 170 includes one or more layers of a dielectric material, such as silicon oxide, silicon nitride, or high-K dielectric material, other suitable dielectric material, and/or combinations thereof. Examples of high-K dielectric material include HfO₂, HfSiO, HfSiON, HfTaO, HfTiO, HfZrO, zirconium oxide, aluminum oxide, titanium oxide, hafnium dioxide-alumina (HfO₂—Al₂O₃) alloy, other suitable high-K dielectric materials, and/or combinations thereof. The gate dielectric layer 170 may be formed by CVD, ALD or any suitable deposition technique. The gate electrode layer 172 may include one or more layers of conductive material, such as polysilicon, aluminum, copper, titanium, tantalum, tungsten, cobalt, molybdenum, tantalum nitride, nickel silicide, cobalt silicide, TiN, WN, TiAl, TiAlN, TaCN, TaC, TaSiN, metal alloys, other suitable materials, and/or any combinations thereof. The gate electrode layer 172 may be formed by CVD, ALD, electro-plating, or other suitable deposition technique. The gate electrode layer 172 may be also deposited over the upper surface of the ILD layer 163. The gate dielectric layer 170 and the gate electrode layer 172 formed over the ILD layer 163 are then removed by using, for example, CMP, until the top surface of the ILD layer 163 is exposed.

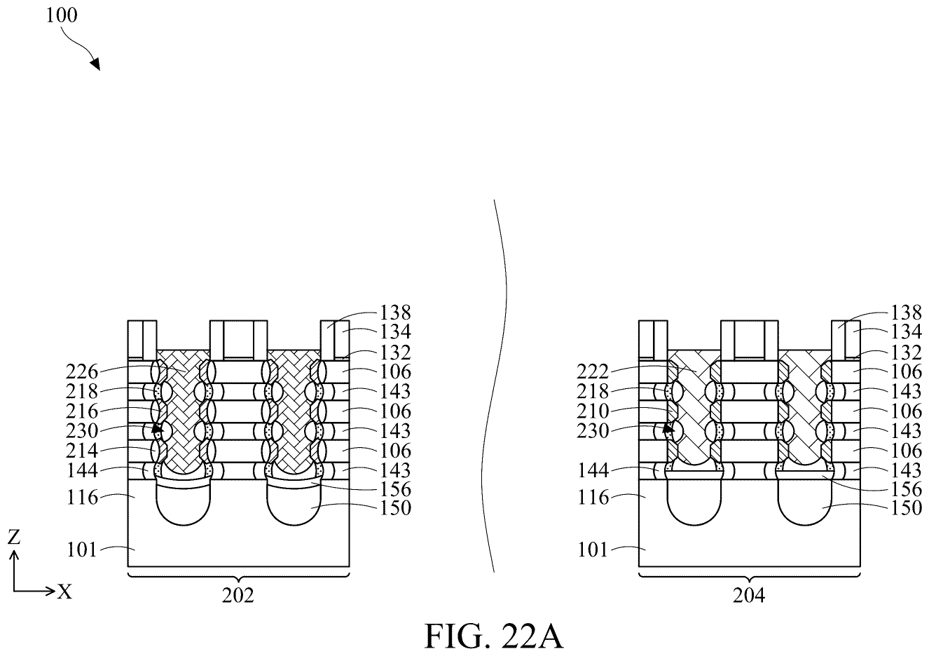

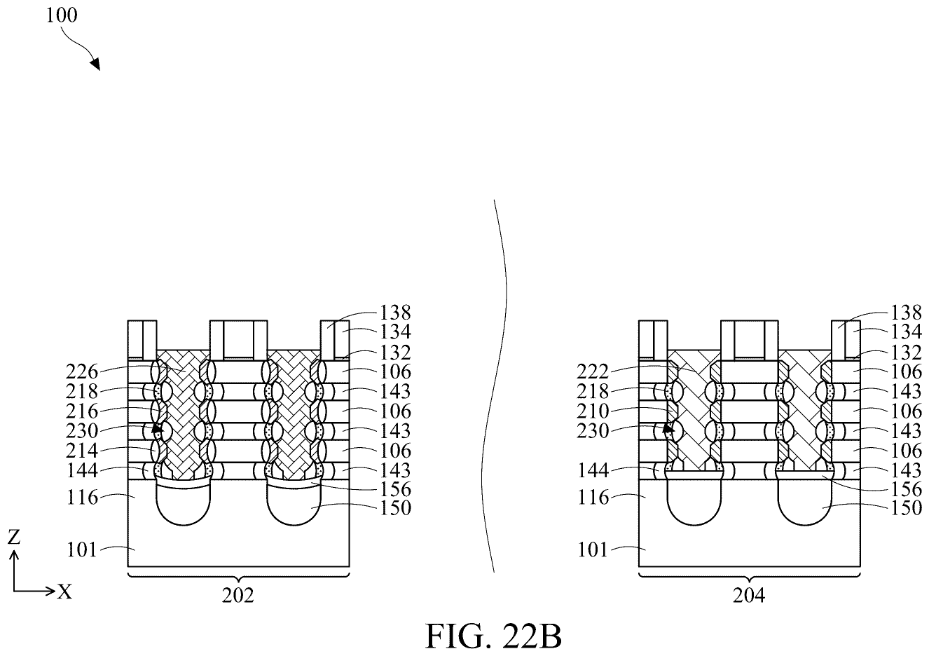

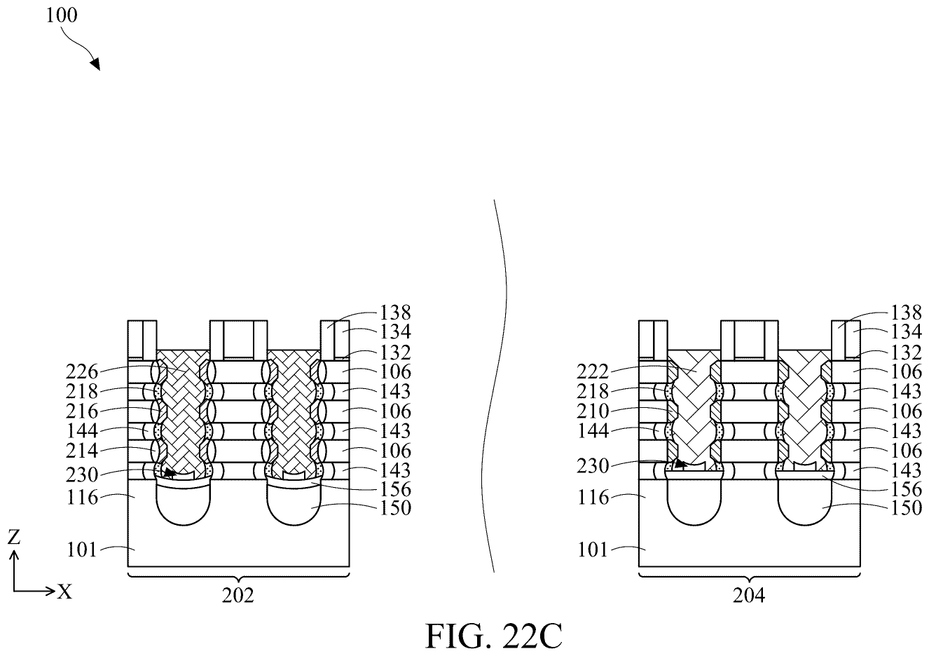

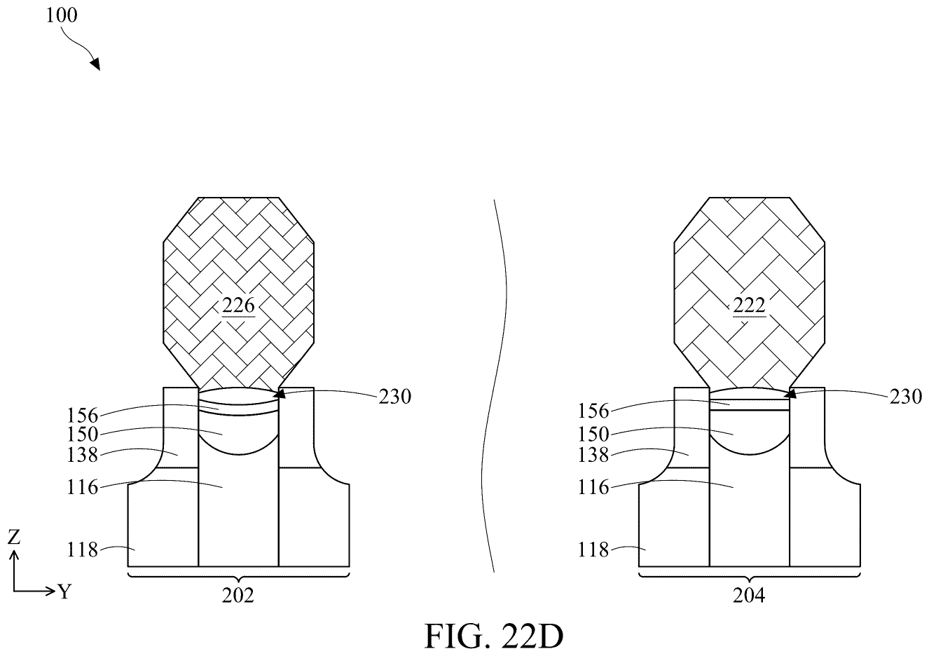

FIGS. 22A, 22B, and 22C are cross-sectional side views of one of various stages of manufacturing the semiconductor device structure 100 taken along line A-A of FIG. 5, in accordance with alternative embodiments. In some embodiments, air gaps 230 may be formed between the semiconductor material 226 and the dielectric spacers 218 and between the semiconductor material 226 and the dielectric layer 156 in the PMOS region 202, as shown in FIG. 22A. In some embodiments, the air gaps 230 may be formed between the semiconductor material 222 and the dielectric spacers 218 and between the semiconductor material 222 and the dielectric layer 156 in the NMOS region 204, as shown in FIG. 22A. The air gaps 230 may be formed as a result of having the dielectric spacers 218. In some embodiments, as shown in FIG. 22B, the semiconductor material 226 is in contact with a center portion of the dielectric layer 156 in the PMOS region 202, and the edge portions of the dielectric layer 156 may be exposed in the air gaps 230 in the PMOS region 202. Similarly, the semiconductor material 222 is in contact with a portion of the dielectric layer 156 in the NMOS region 204, and the edge portions of the dielectric layer 156 may be exposed in the air gaps 230 in the NMOS region 204. In some embodiments, as shown in FIG. 22C, the edge portions of the dielectric layer 156 are in contact with the semiconductor material 226 in the PMOS region 202, and the center portion of the dielectric layer 156 is exposed to the air gap 230 in the PMOS region 202. Similarly, the edge portions of the dielectric layer 156 are in contact with the semiconductor material 222 in the NMOS region 204, and the center portion of the dielectric layer 156 is exposed to the air gap 230 in the NMOS region 204. The dielectric spacers 218 are in contact with the semiconductor material 226 in the PMOS region 202 and with the semiconductor material 222 in the NMOS region 204, as shown in FIG. 22C.

In some embodiments, the air gaps 230 are formed in both PMOS region 202 and the NMOS region 204. In some embodiments, the air gaps 230 are formed in one of the PMOS region 202 and the NMOS region 204. Furthermore, the locations of the air gaps 230 may be different in the PMOS region 202 and the NMOS region 204. For example, in some embodiments, the air gaps 230 are formed between the dielectric spacers 218 and the semiconductor material 226 in the PMOS region 202 and the air gaps 230 are not formed between the dielectric spacers 218 and the semiconductor material 222 in the NMOS region 204 due to the thicker dielectric spacers 218 in the PMOS region 202.

FIG. 22D is a cross-sectional side view of one of various stages of manufacturing the semiconductor device structure 100 taken along line B-B of FIG. 5, in accordance with some embodiments. As shown in FIG. 22D, the air gap 230 is formed between the dielectric layer 156 and the semiconductor material 226 in the PMOS region 202 and between the dielectric layer 156 and the semiconductor material 222 in the NMOS region 204.

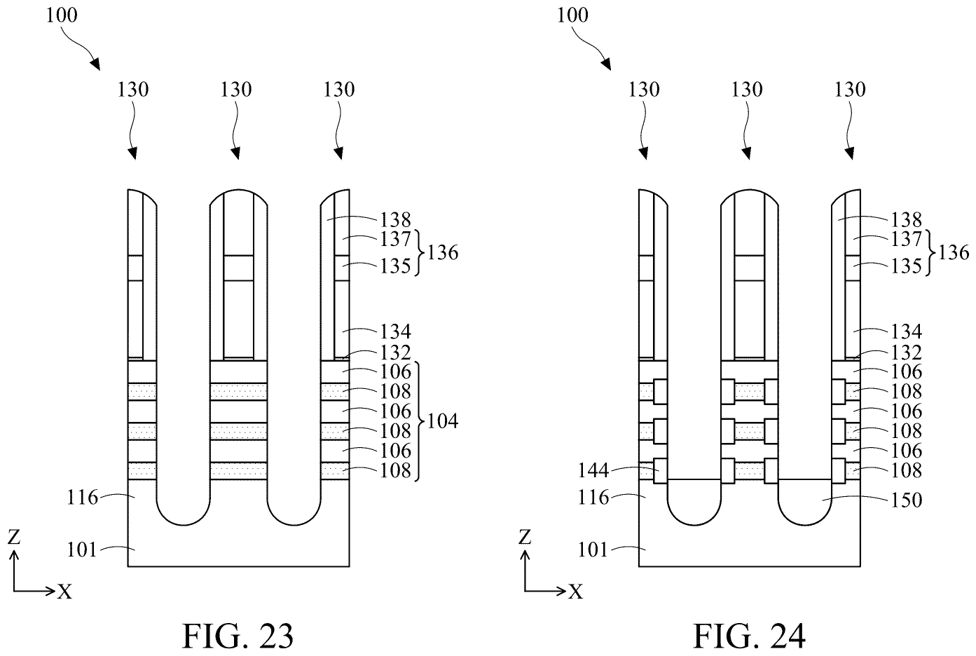

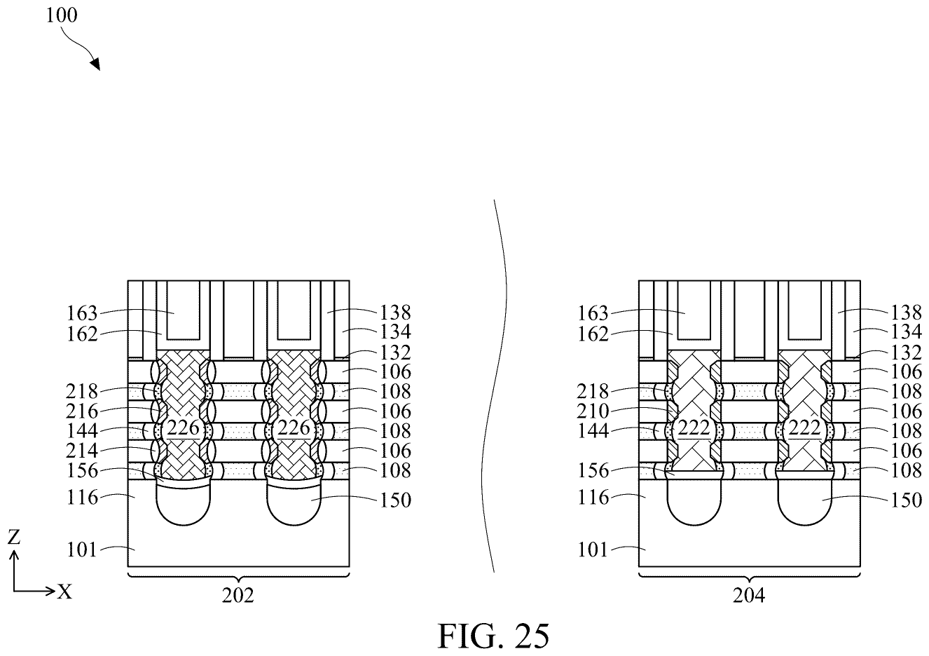

FIGS. 23, 24, and 25 are cross-sectional side views of various stages of manufacturing the semiconductor device structure 100 taken along line A-A of FIG. 5, in accordance with alternative embodiments. FIG. 23 illustrates the semiconductor device structure 100 at the manufacturing stage shown in FIG. 8. Next, instead of removing the second semiconductor layers 108, the second semiconductor layers 108 are laterally recessed, and the dielectric spacers 144 are formed to cap the recessed second semiconductor layers 108 along the X direction, as shown in FIG. 24. Then, processes described in FIG. 13-19 may be performed to form the dielectric layer 156, the dielectric spacers 218, the semiconductor materials 214, 216, 226, the CESL 162, and the ILD layer 163 in the PMOS region 202 and to form the dielectric layer 156, the dielectric spacers 218, the semiconductor materials 210, 222, the CESL 162, and the ILD layer 163 in the NMOS region 204. Compared to the semiconductor device structure 100 shown in FIG. 20, the semiconductor device structure 100 shown in FIG. 25 includes the second semiconductor layers 108 instead of the dielectric material 143. Next, the sacrificial gate structures 130 and the second semiconductor layers 108 are removed, and the gate structures 174 are formed, as shown in FIG. 21.

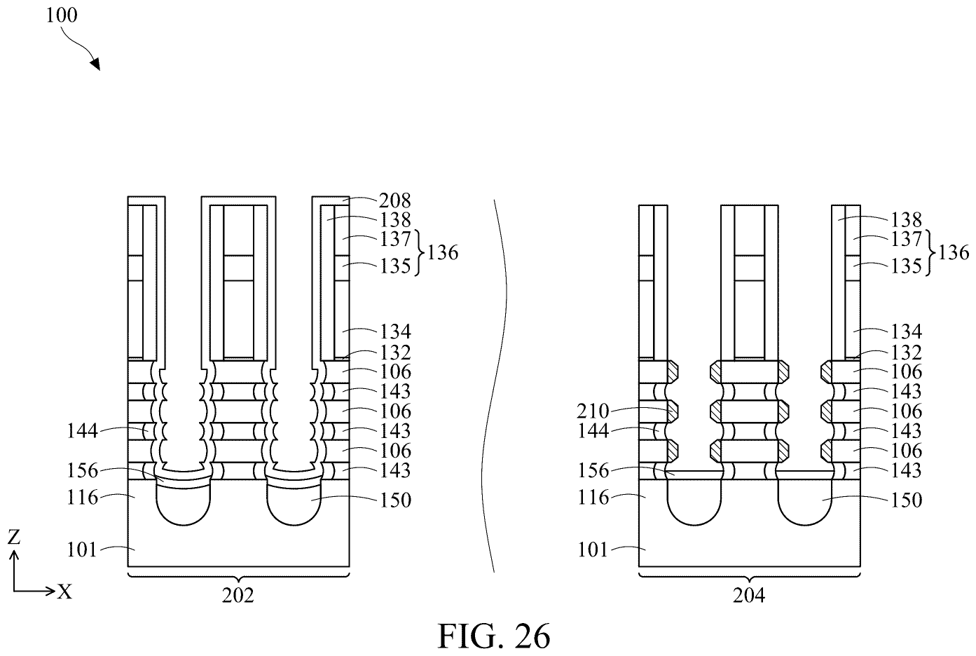

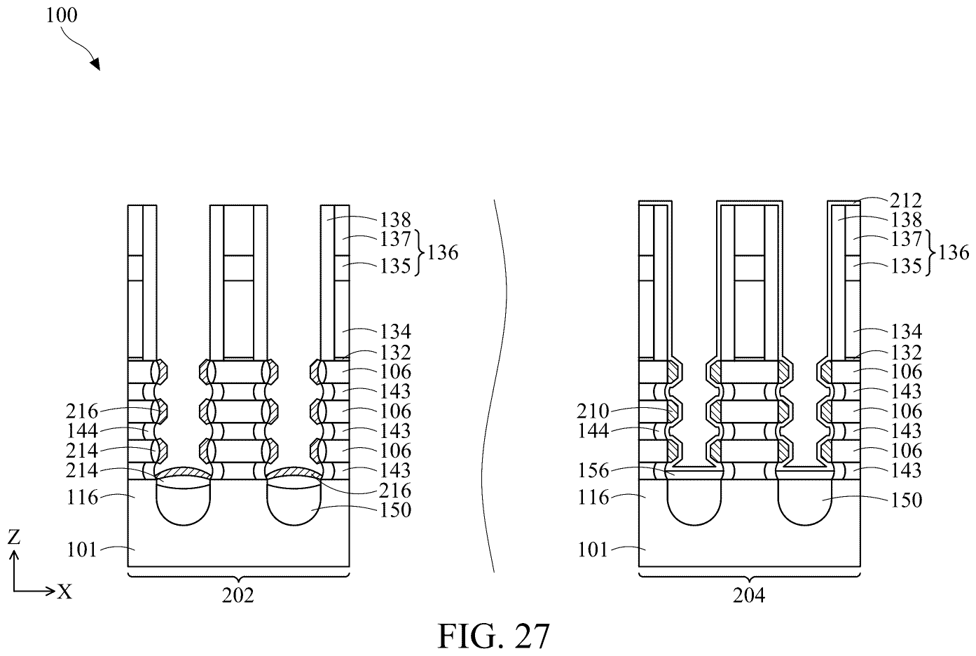

FIGS. 26, 27, 28, 29, and 30 are cross-sectional side views of various stages of manufacturing the semiconductor device structure 100 taken along line A-A of FIG. 5, in accordance with alternative embodiments. FIG. 26 illustrates the semiconductor device structure 100 at the manufacturing stage shown in FIG. 15. Next, as shown in FIG. 27, the mask layer 212 is formed in the NMOS region 204, and the dielectric layer 156 is removed in the PMOS region 202. The dielectric layer 156 may be removed by any suitable process. In some embodiments, the dielectric layer 156 is removed by a selective etch process that does not substantially affect the spacers 138, the dielectric spacers 144, and the first semiconductor layers 106. After removing the dielectric layer 156 in the PMOS region 202, the semiconductor material 214 is formed. As shown in FIG. 27, the semiconductor material 214 is also formed on the semiconductor layer 150. Next, the semiconductor material 216 is formed on the semiconductor material 214. As shown in FIG. 27, the semiconductor material 216 is also formed on the semiconductor material 214 that is formed on the semiconductor layer 150.

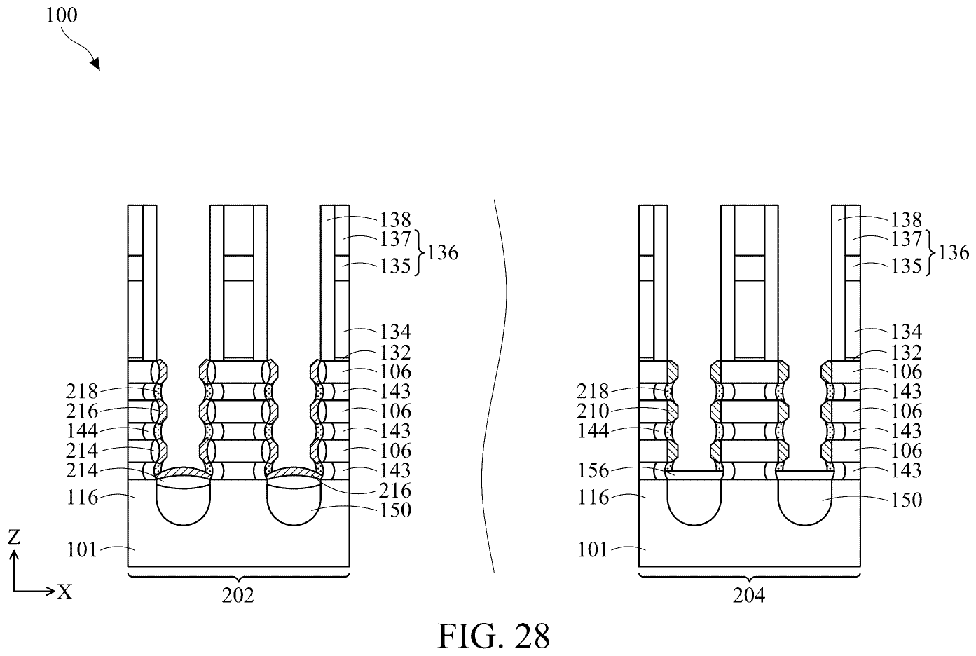

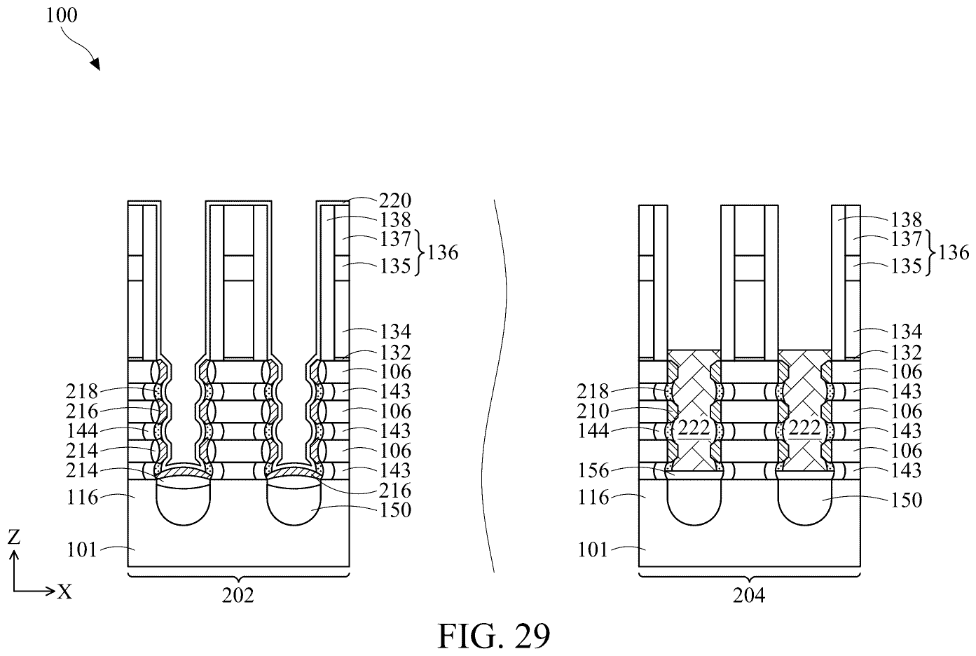

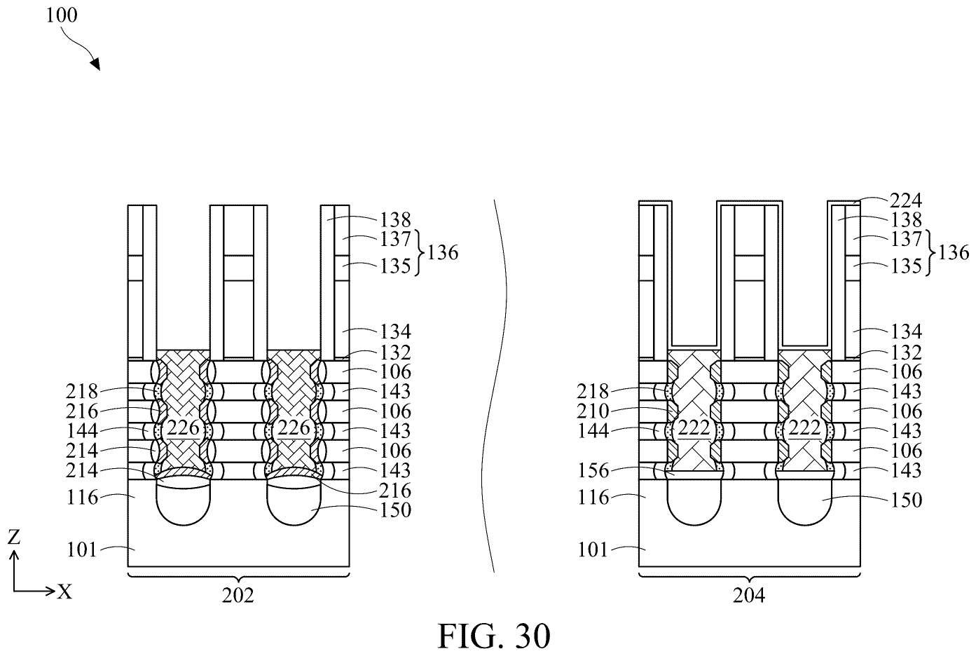

As shown in FIG. 28, the mask layer 212 in the NMOS region 204 is removed, and the dielectric spacers 218 are formed in the PMOS region 202 and the NMOS region 204. Next, a mask layer 220 is formed in the PMOS region 202, and the semiconductor material 222 is formed in the NMOS region 204, as shown in FIG. 29. As shown in FIG. 30, the mask layer 220 is removed from the PMOS region 202, the mask layer 224 is formed in the NMOS region 204, and the semiconductor material 226 is formed in the PMOS region 202. Processes described in FIGS. 20 and 21 may be performed to form the CESL 162, the ILD layer 163, and the gate structures 174.

In some embodiments, similar to the processes described in FIGS. 23, 24, and 25, the second semiconductor layers 108 are not completely removed before forming the dielectric spacers 144, and the dielectric material 143 is replaced with the second semiconductor layers 108 in FIG. 30.

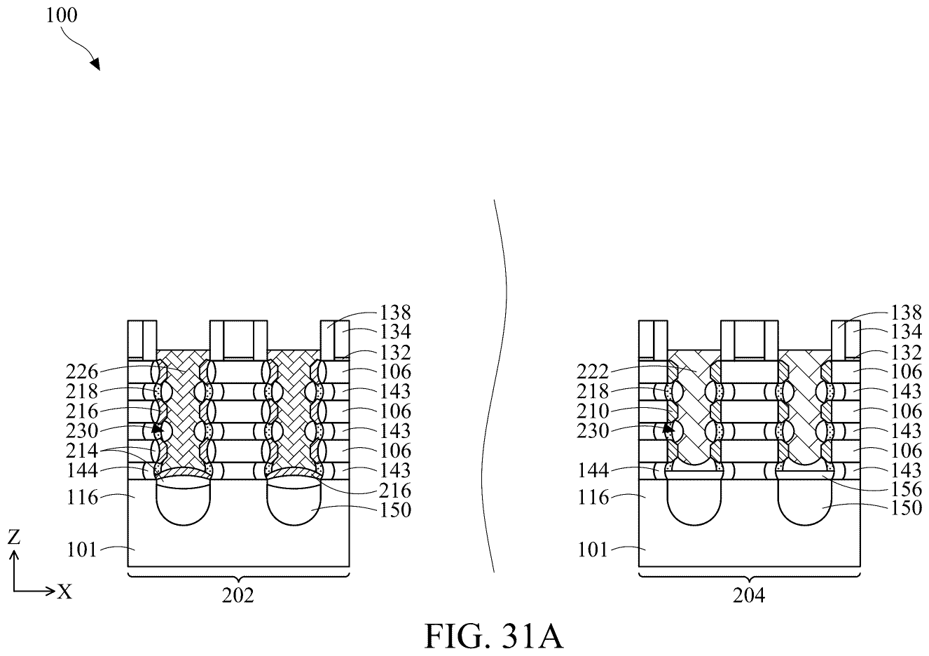

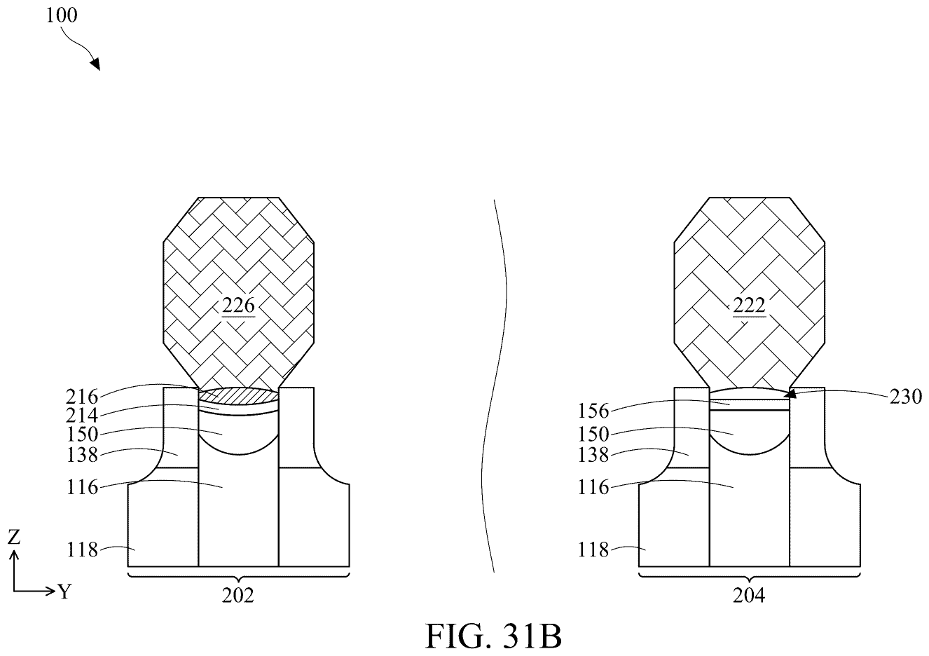

FIG. 31A is a cross-sectional side view of one of various stages of manufacturing the semiconductor device structure 100 taken along line A-A of FIG. 5, in accordance with alternative embodiments. FIG. 31B is a cross-sectional side view of one of various stages of manufacturing the semiconductor device structure 100 taken along line B-B of FIG. 5, in accordance with alternative embodiments. As shown in FIGS. 31A and 31B, the semiconductor material 226 is formed from the semiconductor material 216 in the PMOS region 202. As a result, in some embodiments, the air gaps 230 are not formed at the bottom of the semiconductor material 226 in the PMOS region 202. In some embodiments, the semiconductor material 222 is not formed from the dielectric layer 156 in the NMOS region 204, and the air gap 230 is formed at the bottom of the semiconductor material 222 in the NMOS region 204.

Embodiments of the present disclosure provide a semiconductor device structure and methods of forming the same. The structure includes a first dielectric spacer 144 and a second dielectric spacer 218 disposed between the source/drain region and the gate electrode layer 172. Some embodiments may achieve advantages. For example, as the distance between adjacent gate structures 174 gets smaller, two dielectric spacers 144, 218 with the combined thickness can lead to reduced Ceff.

An embodiment is a semiconductor device structure. The structure includes a first semiconductor layer disposed in a first region, a second semiconductor layer disposed over the first semiconductor layer in the first region, a first gate electrode layer disposed between the first and second semiconductor layers in the first region, a first source/drain region disposed adjacent the first and second semiconductor layers in the first region, and a first dielectric spacer disposed between the first source/drain region and the first gate electrode layer in the first region. The first dielectric spacer has a first thickness. The structure further includes a third semiconductor layer disposed in a second region, a fourth semiconductor layer disposed over the third semiconductor layer in the second region, a second gate electrode layer disposed between the third and fourth semiconductor layers in the second region, a second source/drain region disposed adjacent the third and fourth semiconductor layers in the second region, and a second dielectric spacer disposed between the second source/drain region and the second gate electrode layer in the second region. The second dielectric spacer has a second thickness smaller than the first thickness.

Another embodiment is a semiconductor device structure. The structure includes a first semiconductor layer, a second semiconductor layer disposed over the first semiconductor layer, a gate dielectric layer disposed between the first and second semiconductor layers, a first dielectric spacer disposed adjacent the gate dielectric layer, a second dielectric spacer disposed adjacent the first dielectric spacer, and a source/drain region disposed adjacent the first and second semiconductor layers and the second dielectric spacer. A first air gap is formed between the source/drain region and the second dielectric spacer.

A further embodiment is a method. The method includes forming a sacrificial gate structure over a first portion of a fin structure, and the fin structure includes a plurality of first semiconductor layers. The method further includes recessing a second portion of the fin structure to expose a substrate portion, forming first dielectric spacers between the first semiconductor layers, laterally recessing the first semiconductor layers, depositing a first semiconductor material on the recessed first semiconductor layers, depositing a second semiconductor material on the first semiconductor material, and forming second dielectric spacers on corresponding first dielectric spacers.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A semiconductor device structure, comprising:
a first semiconductor layer disposed in a first region;
a second semiconductor layer disposed over the first semiconductor layer in the first region;
a first gate electrode layer disposed between the first and second semiconductor layers in the first region;
a first source/drain region disposed adjacent the first and second semiconductor layers in the first region;
a first dielectric spacer disposed between the first source/drain region and the first gate electrode layer in the first region, wherein the first dielectric spacer has a first thickness;
a third semiconductor layer disposed in a second region;
a fourth semiconductor layer disposed over the third semiconductor layer in the second region;
a second gate electrode layer disposed between the third and fourth semiconductor layers in the second region;
a second source/drain region disposed adjacent the third and fourth semiconductor layers in the second region; and
a second dielectric spacer disposed between the second source/drain region and the second gate electrode layer in the second region, wherein the second dielectric spacer has a second thickness smaller than the first thickness.

2. The semiconductor device structure of claim 1, further comprising a third dielectric spacer disposed between the first dielectric spacer and the first gate electrode layer in the first region and a fourth dielectric spacer disposed between the second dielectric spacer and the second gate electrode layer in the second region.

3. The semiconductor device structure of claim 2, wherein a thickness of the third dielectric spacer is same as a thickness of the fourth dielectric spacer.

4. The semiconductor device structure of claim 2, wherein the first and third dielectric spacers comprise a same material, and the second and fourth dielectric spacers comprise a same material.

5. The semiconductor device structure of claim 2, wherein the first and third dielectric spacers comprise different materials, and the second and fourth dielectric spacers comprise different materials.

6. The semiconductor device structure of claim 1, wherein the first source/drain region comprises a first semiconductor material in contact with the first and second semiconductor layers, a second semiconductor material in contact with the first semiconductor material, and a third semiconductor material in contact with the second semiconductor material.

7. The semiconductor device structure of claim 6, wherein the second and third semiconductor materials are in contact with the first dielectric spacer.

8. The semiconductor device structure of claim 6, wherein the second source/drain region comprises a fourth semiconductor material in contact with the third and fourth semiconductor layers, and a fifth semiconductor material in contact with the fourth semiconductor material.

9. The semiconductor device structure of claim 8, wherein the fourth and fifth semiconductor materials are in contact with the second dielectric spacer.

10. A semiconductor device structure, comprising:
a first semiconductor layer;
a second semiconductor layer disposed over the first semiconductor layer;
a gate dielectric layer disposed between the first and second semiconductor layers;
a first dielectric spacer disposed adjacent the gate dielectric layer;
a second dielectric spacer disposed adjacent the first dielectric spacer; and
a source/drain region disposed adjacent the first and second semiconductor layers and the second dielectric spacer, wherein a first air gap is formed between the source/drain region and the second dielectric spacer.

11. The semiconductor device structure of claim 10, further comprising a dielectric layer disposed below the source/drain region.

12. The semiconductor device structure of claim 11, wherein a second air gap is formed between the source/drain region and the dielectric layer.

13. The semiconductor device structure of claim 11, wherein the source/drain region is in contact with the dielectric layer.

14. The semiconductor device structure of claim 10, wherein the source/drain region comprises a first semiconductor material in contact with the first and second semiconductor layers, a second semiconductor material in contact with the first semiconductor material, and a third semiconductor material in contact with the second semiconductor material.

15. The semiconductor device structure of claim 14, wherein the first air gap is formed between the third semiconductor material and the second dielectric spacer.

16. A method for forming a semiconductor device structure, comprising:
forming a sacrificial gate structure over a first portion of a fin structure, wherein the fin structure comprises a plurality of first semiconductor layers;
recessing a second portion of the fin structure to expose a substrate portion;
forming first dielectric spacers between the first semiconductor layers;
laterally recessing the first semiconductor layers;
depositing a first semiconductor material on the recessed first semiconductor layers;
depositing a second semiconductor material on the first semiconductor material; and
forming second dielectric spacers on corresponding first dielectric spacers.

17. The method of claim 16, wherein the forming of the first dielectric spacers comprises:
laterally recessing a dielectric material disposed between adjacent first semiconductor layers;
depositing a dielectric layer; and
removing portions of the dielectric layer.

18. The method of claim 16, wherein the forming of the first dielectric spacers comprises:
laterally recessing second semiconductor layers disposed between adjacent first semiconductor layers;
depositing a dielectric layer; and
removing portions of the dielectric layer.

19. The method of claim 16, further comprising forming a semiconductor layer on the exposed substrate portion and forming a dielectric layer on the semiconductor layer, wherein the second dielectric spacers are formed on the dielectric layer.

20. The method of claim 16, further comprising forming a semiconductor layer on the exposed substrate portion, wherein the first semiconductor material is deposited on the semiconductor layer.
